(19) United States
(12) Patent Application Publication
(10) Pub. No.: US 2025/0227948 A1
(43) Pub. Date: Jul. 10, 2025

(54) SEMICONDUCTOR DEVICE

(71) Applicant: Nippon Telegraph and Telephone Corporation, Tokyo (JP)

(72) Inventors: Takuya Tsutsumi, Tokyo (JP); Taro Sasaki, Tokyo (JP)

(21) Appl. No.: 18/854,024

(22) PCT Filed: May 19, 2022
(86) PCT No.: PCT/JP2022/020824

§ 371 Date: Oct. 3, 2024

(51) Int. Cl. H10D 30/47; H10D 62/17

(52) U.S. Cl. CPC H10D 30/476; H10D 62/221

(57) ABSTRACT

A semiconductor device according to embodiments of the present invention is a field-effect transistor including a gate electrode between a source electrode and a drain electrode, wherein carriers travel between the source electrode and the drain electrode, a channel control layer is provided between a channel through with the carriers travel and the gate electrode, a recess is disposed at least in part of a surface in contact with the gate electrode on a source electrode side in the channel control layer, and a part of the gate electrode is filled in the recess.

### CROSS-REFERENCE TO RELATED APPLICATIONS

This application is a national phase entry of PCT Application No. PCT/JP2022/020824, filed on May 19, 2022, which application is hereby incorporated herein by reference.

### TECHNICAL FIELD

The present invention relates to a semiconductor device with a field-effect transistor structure.

### BACKGROUND

The properties of terahertz waves in an electromagnetic wave frequency band from 0.3 to 3 THz provide the potential to create and implement new and unprecedented applications, such as high-speed wireless communication at speeds faster than 100 Gb/s, non-destructive inspection using 3D imaging, component analysis using electromagnetic absorption, and atmospheric sensing from outer space.

To implement terahertz-wave applications, electronic devices constituting these applications are also required to have better high-frequency characteristics. Field-effect transistors made of compound semiconductors with particularly high electron mobility in terms of physical properties are used as electronic devices with good high-frequency characteristics. For further development of terahertz waves in the future, field-effect transistors with better high frequency characteristics will be needed.

A field-effect transistor includes a semiconductor (channel) layer, a gate electrode formed on the semiconductor (channel) layer, a source electrode formed on both sides of the gate electrode in a horizontal direction, and a drain electrode. In the field-effect transistor, when a potential is applied to the gate electrode, carriers (electrons) traveling in the channel layer between the source electrode and the drain electrode are modulated in accordance with the intensity of the applied potential.

To improve the high frequency characteristics of a field-effect transistor, it is necessary to increase a modulation speed in the channel layer. Indices indicating the high frequency characteristics of a field-effect transistor include a cutoff frequency (ft) and a maximum operating frequency (fmax). Among these, improvement in fmax is especially critical from the viewpoint of amplification in analog electronic circuits. fmax indicates a frequency at which the field-effect transistor has a power gain of 1.

It is critical to shorten a length of the gate electrode (gate length) to improve fmax in the field-effect transistor.

Furthermore, when a high bias is applied to the drain electrode, hot electrons are generated in the channel layer between the gate electrode and the drain electrode in the field-effect transistor. This produces electron-hole pairs and increases drain conductance. fmax deteriorates accordingly. Therefore, drain conductance is required to be reduced in order to improve fmax.

A high electron mobility field-effect transistor (HEMT) is a type of a field-effect transistor with enhanced high frequency characteristics. An HEMT includes semiconductor layers such as a buffer layer, a channel layer, a barrier layer, and a capping layer on a semiconductor substrate.

Carriers are supplied from a δ-doped layer formed in the barrier layer to the channel layer to form a two-dimensional electron gas in the HEMT, forming a conduction channel between a source electrode and a drain electrode. When a potential is applied to the gate electrode, the concentration of the two-dimensional electron gas is modulated in response to the intensity of the applied potential, whereby electrons move through the conduction channel between the source electrode and the drain electrode.

Further, the channel layer in which the two-dimensional electron gas is formed and the carriers travel is spatially separated from an electron supply layer into which impurities are introduced in the HEMT. Accordingly, the HEMT enables scattering due to impurities in the conduction channel to be suppressed, so that electron mobility and high frequency characteristics can be improved.

Therefore, it is important to shorten the length of the gate electrode (gate length), reduce drain conductance, and further, employ a high-mobility material in the channel layer in order to improve fmax in an HEMT.

Shortening of the gate length is already achieved by scaling in field-effect transistors including HEMTs.

Furthermore, application of a high-mobility channel layer in the HEMT by a configuration, as illustrated in FIG. 8, has been disclosed in which a first channel layer 803 made of InGaAs where the In composition x is ≤0.8, a second channel layer 804 made of InGaAs or InAs where the In composition x satisfies 0.8<x≤1, a third channel layer 805 made of InGaAs where the In composition x is ≤0.8, a spacer layer 806 made of InAlAs, an electron supply layer 807, and a barrier layer 808 are formed in that order (for example, see PTL 1).

Another configuration is disclosed aiming to reduce drain conductance, as illustrated in FIG. 9, in which a structure (asymmetric recess structure) 912 having an asymmetric cavity without a capping layer 906 is formed so that a distance between a gate electrode 914 and a drain electrode 908 is longer than a distance between the gate electrode 914 and a source electrode 907 (see PTL 2). A substrate 901, a buffer layer 902, a channel layer 903, a barrier layer 904, an electron supply layer 905, a first insulation layer 909, an asymmetric recess forming opening 911, a second insulation layer 913, and a passivation layer 921 are further provided.

Similarly, an asymmetric recess structure 1012/1013 is disclosed as illustrated in FIG. 10, in which a capping layer 1018 is removed such that a distance between a gate electrode 1011 and a drain electrode 1010 is longer than a distance between the gate electrode 1011 and a source electrode 1009 (see PTL 3). The structure further includes a substrate 1001, a buffer layer 1002, a channel layer 1003, a barrier layer 1004, a passivation layer 1005, an electron supply layer 1008, an insulation film 1014, and an opening 1015.

According to these asymmetric recess structures, generation of hot electrons can be suppressed when a high drain bias is applied by intentionally causing carrier depletion in a region on a drain electrode side. Therefore, drain conductance can be reduced and fmax can be improved.

### CITATION LIST

### Patent Literature

PTL 1 Japanese Patent No. 5525013
PTL 2 Japanese Patent No. 6810014
PTL 3 Japanese Patent No. 5662547

### SUMMARY

### Technical Problem

However, shortening the length of the gate electrode (gate length) causes short channel effects such as a decreased threshold voltage in the field-effect transistor.

Furthermore, the configuration using the high-mobility channel layer has significant generation of hot electrons in the channel layer between the gate electrode and the drain electrode when a high bias is applied to the drain electrode since the high-mobility channel material, such as InAs, has a small bandgap. This makes fmax worse.

The configuration having the asymmetric recess structure also has issues that electrons are not induced in the barrier layer near the cavity where no capping layer is present in the region on the drain electrode side. The barrier layer in which electrons are not induced becomes longer, resulting in a significantly increased drain resistance. When the drain resistance increases, ft deteriorates, which in turn significantly deteriorates fmax.

Even if the drain conductance is reduced by forming a long cavity without a capping layer in the region on the drain electrode, the drain resistance increases and cancels out the effect of improving fmax. Consequently, even with the asymmetric recess structure, the effect of improving fmax is limited to a certain extent and is insufficiently achieved.

### Solution to Problem

To address the challenges above, a semiconductor device according to embodiments of the present invention is a field-effect transistor including a gate electrode between a source electrode and a drain electrode, wherein carriers travel between the source electrode and the drain electrode, a channel control layer is provided between a channel through which the carriers travel and the gate electrode, a recess is disposed at least in part of a surface in contact with the gate electrode on a source electrode side in the channel control layer, and a part of the gate electrode is filled in the recess.

### Advantageous Effects of Embodiments of the Invention

According to embodiments of the present invention, it is possible to provide a semiconductor device with excellent high frequency characteristics.

### BRIEF DESCRIPTION OF THE DRAWINGS

FIG. 1 is a schematic cross-sectional view illustrating a configuration of a semiconductor device according to a first embodiment of the present invention.

FIG. 2 is a schematic cross-sectional view illustrating a configuration of a semiconductor device according to a second embodiment of the present invention.

FIG. 3 is a schematic cross-sectional view illustrating a configuration of a semiconductor device according to a third embodiment of the present invention.

FIG. 4 is a schematic cross-sectional view illustrating a configuration of a semiconductor device according to a fourth embodiment of the present invention.

FIG. 5 is a schematic cross-sectional view illustrating a configuration of a semiconductor device according to a fifth embodiment of the present invention.

FIG. 6 is a schematic cross-sectional view illustrating one example of the configuration of the semiconductor device according to the fifth embodiment of the present invention.

FIG. 7 is a schematic cross-sectional view illustrating one example of the configuration of the semiconductor device according to an embodiment of the present invention.

FIG. 8 is a cross-sectional view illustrating one example of a layer structure of a conventional semiconductor device.

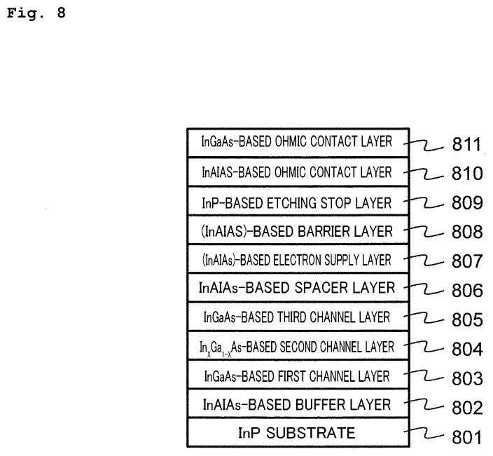

FIG. 9 is a cross-sectional view illustrating one example of a configuration of the conventional semiconductor device.

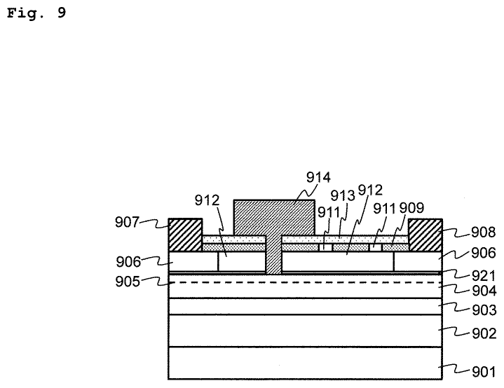

FIG. 10 is a cross-sectional view illustrating one example of the configuration of the conventional semiconductor device.

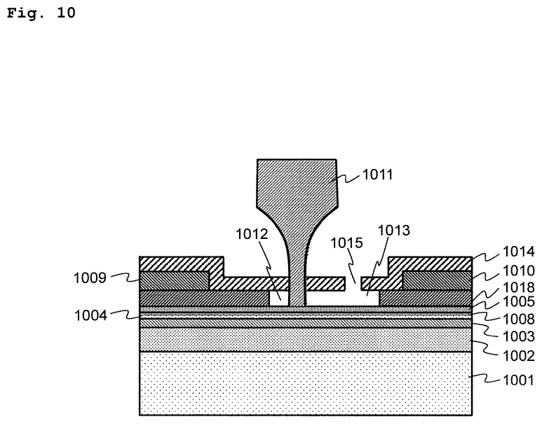

### DETAILED DESCRIPTION OF ILLUSTRATIVE EMBODIMENTS

### First Embodiment

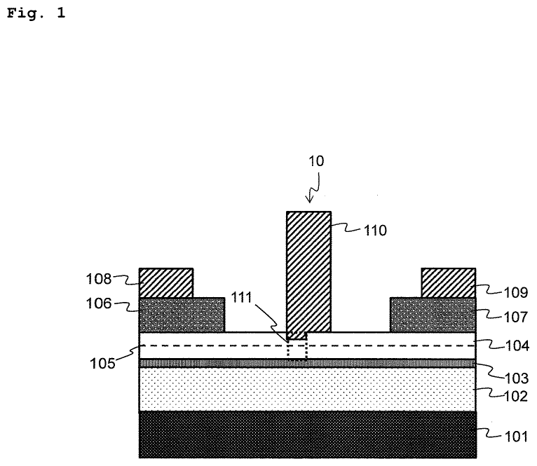

A semiconductor device according to a first embodiment of the present invention will be described hereinafter with reference to FIG. 1.

### Configuration of Semiconductor Device

As shown in FIG. 1, a semiconductor device 10 according to the present embodiment includes a buffer layer 102, a channel layer 103, a barrier layer (hereinafter also referred to as a “channel control layer”) 104, a δ-doped layer 105 within the barrier layer 104, and capping layers 106 and 107 in order from a first side of a substrate 101.

Furthermore, a source electrode 108 and a drain electrode 109, which are ohmic electrodes, are provided on the capping layers 106 and 107.

A gate electrode 110 is provided on the barrier layer 104 between the source electrode 108 and the drain electrode 109. An example is presented in which the gate electrode 110 is arranged near the center between the source electrode 108 and the drain electrode 109; however, the gate electrode 110 is not limited thereto and may be arranged at any position between the source electrode 108 and the drain electrode 109.

Further, the barrier layer 104 has a recess in a part (one region) of its surface, and the gate electrode 110 is formed on a surface of the barrier layer 104 including the recess. In other words, a part (one region) of the surface of the barrier layer 104 in contact with the gate electrode 110 has a recess. Accordingly, the barrier layer 104 directly under the gate electrode 110 is thin in a predetermined region (one region) and thick in the other region.

A portion consisting of the gate electrode 110 and the barrier layer 104 (recess) in the predetermined region (one region) is referred to as a “barrier recessed portion” 111 (a dotted-square portion in the drawing).

The barrier recessed portion 111, that is, the recess, is arranged at an end portion on a source electrode side in the region where the barrier layer 104 is in contact with the gate electrode 110. The recess may be disposed anywhere on the source electrode side, instead of the center of the barrier recessed portion 111.

In the barrier layer 104 with which the gate electrode 110 is in contact, the barrier recessed portion 111 is formed such that a part of the gate electrode 110 is filled in the recess of the barrier layer 104.

A structure including this barrier recessed portion 111 is fabricated by etching a recess in the predetermined region on the surface of the barrier layer 104 and then forming the gate electrode 110.

An InP-based HEMT will be described as one example of the semiconductor device according to the present embodiment. The InP-based HEMT is generally used as a high-frequency HEMT.

In the InP-based HEMT, the buffer layer 102 is a buffer region provided during crystal growth on the semiconductor (InP) substrate 101. Non-doped InAlAs is generally used as the material, and a thickness thereof is about 10 to 1000 nm.

The channel layer 103 functions as a channel through which carriers travel between the source electrode 108 and the drain electrode 109, and is a region where carriers are modulated by an electric field from the gate electrode 110. The higher the electron mobility is in the channel layer 103, the higher the high frequency performance can be. Non-doped InAs is used as the material. InₓGa₁₋ₓAs and InSb can also be used. Composite channel structures with different compositions are also applicable. The total thickness of the channel layer 103 is approximately 3 to 20 nm.

The barrier layer (channel control layer) 104 is a region for forming a Schottky junction with the gate electrode 110. InP is used as the material. Additionally, a material having a band gap larger than that of the channel layer 103 and capable of forming a sufficiently high Schottky barrier against the gate electrode 110 can be used, such as InAlAs and InₓGa₁₋ₓAS. Composite barrier structures with different compositions are also applicable. The total thickness of the barrier layer 104 is set to no more than approximately ¼ to ⅕ of the gate length. For example, when the gate length is 50 nm, the thickness of the barrier layer 104 is in a range from 10 nm to 12.5 nm.

The δ-doped layer 105 is formed in a sheet shape in order to supply carriers to the non-doped barrier layer 104. A dopant is an n-type doping impurity such as silicon (Si). The δ-doped layer 105 within the barrier layer 104 is formed approximately in the middle of the barrier layer 104 in a thickness direction (described later).

The capping layers 106 and 107 are respectively formed to achieve a low-resistance ohmic contact with the source electrode 108 and the drain electrode 109, which are ohmic electrodes, without annealing treatment. N-type InP is used as the material. InAlAs and InGaAs can also be used. The thickness of the capping layers 106 and 107 is set such that a sufficiently low contact resistance can be achieved and external parasitic capacitance can be reduced structurally, and is, for example, 5 to 20 nm.

The source electrode 108 and the drain electrode 109, which are ohmic electrodes, are formed to conduct carriers such as electrons to the channel layer 103 via the capping layers 106 and 107 and the barrier layer 104, and each has a metal laminated structure. A laminated structure of Ti/Pt/Au is used as the metal laminated structure. Mo, W, WSi and other elements may be used for the laminated structure.

The gate electrode 110 is formed to modulate electrons in the channel layer 103 by an electric field via the barrier layer 104, and has a metal laminated structure similar to the source electrode 108 and the drain electrode 109. A laminated structure of Ti/Pt/Au is used as the metal laminated structure. Mo, W, WSi and other elements may be used for the laminated structure.

Further, the length (gate length) of the gate electrode 110 is set to about 4 to 5 times the thickness of the barrier layer 104.

The barrier recessed portion 111 is arranged at the gate electrode 110 on the source electrode side. A length of the barrier recessed portion 111 is approximately 20 to 50% of the gate length. For example, when the gate length is about 50 nm, the length of the barrier recessed portion 111 is 10 to 25 nm.

A recess depth of the barrier recessed portion 111 may be any value as long as it is smaller than the thickness of the barrier layer 104. For example, when the thickness of the barrier layer 104 is about 10 nm, the recess depth of the barrier recessed portion 111 is set to 2 to 8 nm.

### Advantageous Effects

In the present embodiment, the distance between the gate electrode and the channel layer (thickness of the barrier layer) is shortened by the barrier recessed structure, and therefore short channel effects such as a decreased threshold voltage can be suppressed.

Since the barrier layer is formed thickly at the end portion of the gate electrode on the drain electrode side, the electric field strength near the end portion of the gate electrode on the drain electrode side is relaxed, thereby suppressing the electric field applied to electrons traveling through the channel layer in the gate region. Consequently, the generation of hot electrons can be suppressed and the drain conductance can be reduced.

Further, in the present embodiment, the drain conductance can be reduced with a configuration in which a sufficient capping layer region (area) in the region on the drain electrode side is ensured, for example, with a configuration that does not have an asymmetric recess structure. In this configuration, electrons are sufficiently induced in the barrier layer in the region on the drain electrode side, and therefore the increased drain resistance can be avoided. In this way, the drain conductance can be reduced without increasing the drain resistance, and therefore fmax can also be improved.

Of course, even in a configuration having an asymmetric recess structure, the drain conductance can be further reduced and fmax can be improved.

In this manner, it is possible to improve fmax by reducing drain conductance in an HEMT structure with a shortened gate length and a high-mobility channel.

According to the semiconductor device of the present embodiment, the increased drain conductance due to generation of hot electrons can be suppressed without increasing drain resistance, and a field-effect transistor having excellent high frequency characteristics can be obtained.

### Second Embodiment

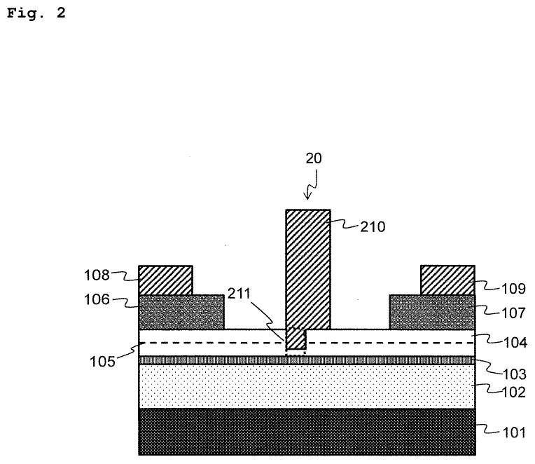

A semiconductor device according to a second embodiment of the present invention will be described hereinafter with reference to FIG. 2.

### Configuration of Semiconductor Device

In the semiconductor device 20 according to the present embodiment, as shown in FIG. 2, a recess depth of a barrier recessed portion 211 is greater than the position (depth) of the δ-doped layer 105 in the barrier layer 104. The other components are the same as in the first embodiment.

In a case where a high-mobility channel is applied to the channel layer in the conventional HEMT structure, the threshold voltage tends to be high, although it depends on the density of the induced electron gas. In a case where the threshold voltage is high, it is necessary to apply high reverse bias to the gate electrode when turning off the HEMT, thereby posing restrictions on the bias design of the circuit.

According to the semiconductor device of the present embodiment, in addition to the advantageous effects of the first embodiment, high fmax can be achieved with the high-mobility channel while the threshold voltage can be reduced, so that the bias design of the circuit can be easily modified.

### Third Embodiment

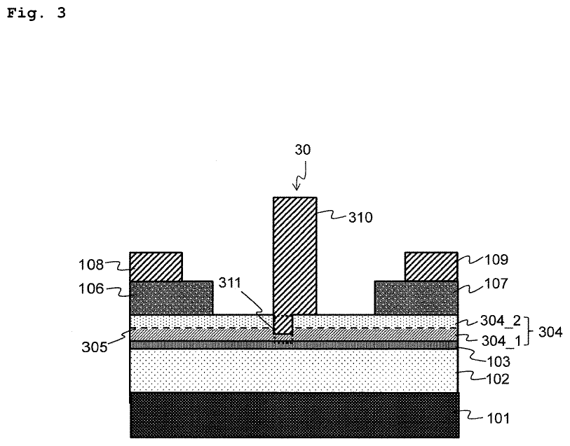

A semiconductor device according to a third embodiment of the present invention will be described hereinafter with reference to FIG. 3.

### Configuration of Semiconductor Device

In the semiconductor device 30 according to the present embodiment, as shown in FIG. 3, a barrier layer 304 is made of different materials on the electrode side (surface side) and the channel layer side. Hereinafter, a barrier layer 304_1 on the channel layer side will be referred to as a “channel layer-side barrier layer”, and a barrier layer 304_2 on the electrode side (surface side) will be referred to as an “electrode-side barrier layer”. The other components are the same as in the first embodiment.

A recess depth of a barrier recessed portion 311 is equal to or greater than a thickness of the electrode-side barrier layer 304_2 and less than the total thickness of the barrier layer 304 (the total thickness of the channel-side barrier layer 304_1 and the electrode-side barrier layer 304_2).

The channel-side barrier layer 304_1 is made of a material with a wider band gap than that of the electrode-side barrier layer 304_2, and for example, InAlAs, InP, and InAlP can be used. Accordingly, a distance between the gate electrode 310 and the channel layer 103 can be effectively shortened.

Further, the electrode-side barrier layer 304_2 is made of a material having a small energy difference with conduction band edges of the capping layers 106 and 107, and for example, InGaAs or InAs can be used. Therefore, the energy difference with the conduction band edges of the capping layers 106 and 107 can be reduced, and further, the ohmic resistance can also be reduced.

A δ-doped layer 305 may be disposed at a boundary between the channel-side barrier layer 304_1 and the electrode-side barrier layer 304_2, may be disposed on the electrode-side barrier layer 304_2, or may be disposed on the channel-side barrier layer 304_1.

According to the semiconductor device of the present embodiment, in addition to the advantageous effects of the first embodiment, the distance between the gate electrode and the channel layer is effectively shortened, so that short channel effects such as threshold voltage drop can be suppressed. Since the drain resistance can be reduced by reducing the ohmic resistance, ft can be further improved, and fmax can also be further improved.

### Fourth Embodiment

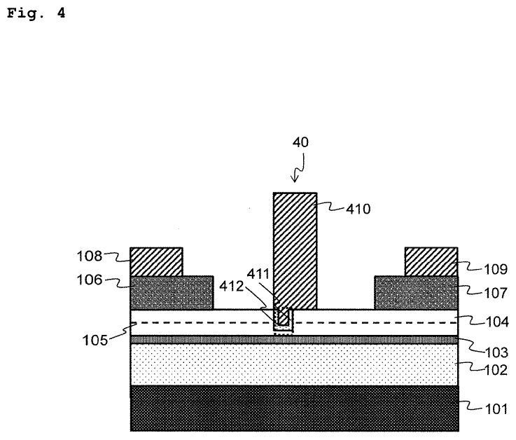

A semiconductor device according to a fourth embodiment of the present invention will be described hereinafter with reference to FIG. 4.

### Configuration of Semiconductor Device

In a semiconductor device 40 according to the present embodiment, as shown in FIG. 4, a high dielectric material 412 is selectively provided between a gate electrode 410 and the barrier layer 104 in a barrier recessed portion 411. The other components are the same as in the first embodiment.

For example, Al₂O₃, HfO₂, ZrO₂, and HfSiO₄ can be used as the high dielectric material 412. A thickness of the high dielectric material 412 is 20 to 50% of a recess depth of the barrier recessed portion 411.

According to the semiconductor device of the present embodiment, in addition to the advantageous effects of the first embodiment, the insulating high dielectric material can be arranged even if the distance between the gate electrode and the channel layer is shortened, whereby leakage current can be reduced.

### Fifth Embodiment

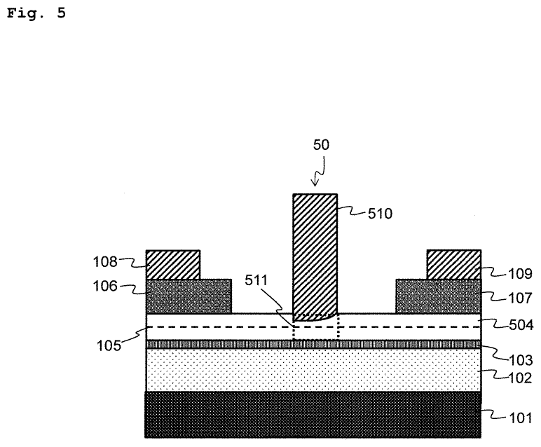

A semiconductor device according to a fifth embodiment of the present invention will be described hereinafter with reference to FIG. 5.

### Configuration of Semiconductor Device

In a semiconductor device 50 according to the present embodiment, as shown in FIG. 5, a barrier recessed portion 511 is provided over the entire area underlying a gate electrode 510.

Specifically, the barrier recessed portion 511 has a constant depth in a predetermined region of the gate electrode 510 on the source electrode side, and gradually becomes shallower toward an opposite end portion of the gate electrode 510 on the drain electrode side.

A configuration of the recess of the barrier recessed portion 511 is not limited thereto, and it may be configured to become continuously shallower from the end portion of the barrier recessed portion 511 on the source electrode side toward the end portion on the drain electrode side.

In other words, a thickness of a barrier layer 504 directly under the gate electrode 510 increases continuously from the end portion on the source electrode side toward the end portion on the drain electrode side in the barrier recessed portion 511.

According to the semiconductor device of the present embodiment, in addition to the advantageous effects of the first embodiment, a recess shape of the barrier recessed portion (the depth from the end portion on the source electrode side toward the end portion on the drain electrode side) is optimized, whereby electric field strength at the end portion of the gate electrode on the drain electrode side can be easily relaxed. Therefore, ft can be further improved, and fmax can also be further improved.

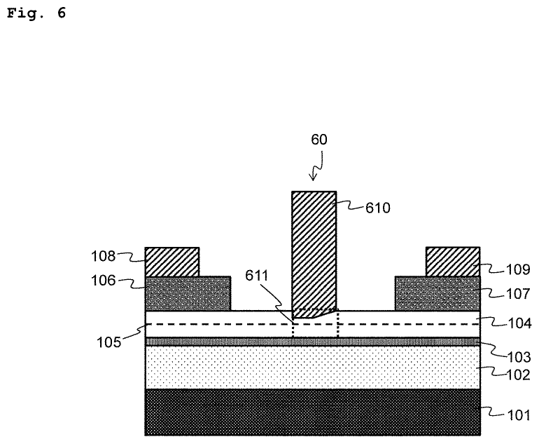

In the semiconductor device according to a variation of the present embodiment, as shown in FIG. 6, a recess of a barrier recessed portion 611 may have a slope structure that becomes linearly shallower from the end portion on the source electrode side toward the end portion on the drain electrode side.

The HEMT is used as the semiconductor device in the embodiments of the present invention, but the present invention is not limited thereto; it can be applied to field-effect transistors such as a MOSFET (metal-oxide-semiconductor field-effect transistor) and a MISFET (metal-insulator-semiconductor FET).

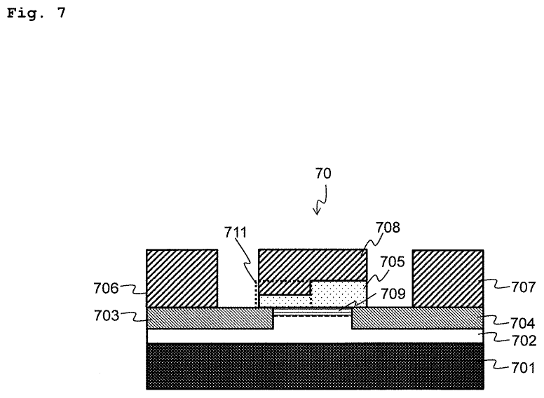

For example, as shown in FIG. 7, a MOSFET 70 includes a silicon (Si) substrate 701, a p-type semiconductor (Si) layer 702, an n-type source region 703, an n-type drain region 704, an oxide film (insulation film or channel control layer) 705, a source electrode 706, a drain electrode 707, and a gate electrode 708. Further, an inversion layer (channel) 709 is formed, and electrons travel as carriers.

In the MOSFET 70, the oxide film (insulation film) 705 has a recess in a part (one region) of its surface, and the gate electrode 708 is formed on a surface of the oxide film 705 including the recess. Accordingly, the oxide film 705 directly under the gate electrode 708 is thin in a predetermined region (one region) and thick in another region. A portion consisting of the gate electrode 708 and the oxide film 705 in the predetermined region (one region) is referred to as a “barrier recessed portion” 711 (a dotted-square portion in the drawing). The barrier recessed portion 711 is arranged at the gate electrode 708 on the source electrode side.

The example is shown in which the p-type semiconductor layer, the n-type source region, and the n-type drain region are employed, however an n-type semiconductor layer, a p-type source region, and a p-type drain region may also be used. In this case, holes travel as carriers.

As described above, in the semiconductor device according to the embodiments of the present invention, the recess is disposed at least in a part of the source electrode side at the interface with the gate electrode in the layer arranged between the gate electrode and the region (channel) through which carriers travel between the source electrode and the drain electrode.

Consequently, the increased drain conductance due to hot electrons generated can be suppressed without increasing drain resistance, and a field-effect transistor having excellent high frequency characteristics can be obtained.

Although the embodiments of the present invention have described examples of structures, dimensions, and materials of each component in the configurations of the semiconductor device and the manufacturing method thereof, the embodiments of the present invention are not limited thereto. Any modifications can be made as long as the modifications have the functions of a semiconductor device and achieve the advantageous effects.

### INDUSTRIAL APPLICABILITY

Embodiments of the present invention relate to a semiconductor device with a field-effect transistor structure, which is applicable to sectors using terahertz waves, including high-speed wireless communication, non-destructive inspection, material analysis and atmospheric sensing.

1.-6. (canceled)

7. A semiconductor device comprising:
a field-effect transistor comprising a gate electrode between a source electrode and a drain electrode;
a channel control layer disposed between a channel through which carriers travel and the gate electrode; and
a recess disposed in a surface of the channel control layer in contact with the gate electrode on a source electrode side, wherein a portion of the gate electrode is disposed in the recess.

8. The semiconductor device according to claim 7, wherein a depth of the recess in the channel control layer becomes shallower from a first end portion on the source electrode side toward a second end portion on a drain electrode side.

9. The semiconductor device according to claim 8, wherein:
the channel comprises a channel layer;
the channel control layer is disposed on the channel layer;
the channel layer comprises a first semiconductor;
the channel control layer comprises a second semiconductor having a larger bandgap than the first semiconductor;
a first capping layer and the source electrode are disposed on a first region of the channel control layer in that order; and
a second capping layer and the drain electrode are disposed on a second region of the channel control layer in that order.

10. The semiconductor device according to claim 9, wherein:
the channel control layer comprises a δ-doped layer; and
the recess extends from the surface in contact with the gate electrode to a position under the δ-doped layer.

11. The semiconductor device according to claim 9, wherein:
the channel control layer comprises a first channel control layer disposed on a channel layer side and a second channel control layer disposed on a gate electrode side; and
a bandgap of the first channel control layer is larger than a bandgap of the second channel control layer.

12. The semiconductor device according to claim 9, further comprising a high dielectric material disposed at a boundary between the channel control layer and the gate electrode in the recess.

13. The semiconductor device according to claim 7, wherein:
the channel comprises a channel layer;
the channel control layer is disposed on the channel;
the channel layer comprises a first semiconductor; and
the channel control layer comprises a second semiconductor having a larger bandgap than the first semiconductor.

14. The semiconductor device according to claim 13, wherein:
a first capping layer and the source electrode are disposed on a first region of the channel control layer in that order; and
a second capping layer and the drain electrode are disposed on a second region of the channel control layer in that order.

15. The semiconductor device according to claim 7, wherein a thickness of the channel control layer underlying an end portion of the gate electrode on the source electrode side is less than the thickness of the channel control layer underlying an opposite end portion of the gate electrode on a drain electrode side.

16. The semiconductor device according to claim 15, wherein the thickness of the channel control layer becomes gradually thicker from the end portion of the gate electrode on the source electrode side to the opposite end portion of the gate electrode on the drain electrode side.

17. A semiconductor device comprising:
a channel layer disposed on a substrate;
a barrier layer disposed on the channel layer, the barrier layer comprising a recess in a first portion of an upper surface thereof;
a source electrode disposed on a second portion of the upper surface of the barrier layer;
a drain electrode disposed on a third portion of the upper surface of the barrier layer; and
a gate electrode disposed between the source electrode and the drain electrode on the first portion of the upper surface of the barrier layer, wherein a portion of the gate electrode is disposed in the recess in the barrier layer.

18. The semiconductor device according to claim 17, wherein a depth of the recess in the barrier layer becomes shallower from a first end portion on a source electrode side toward a second end portion on a drain electrode side.

19. The semiconductor device according to claim 18, wherein:
the channel layer comprises a first semiconductor;
the barrier layer comprises a second semiconductor having a larger bandgap than the first semiconductor;
a first capping layer is disposed on the second portion of the upper surface of the barrier layer between the barrier layer and the source electrode; and
a second capping layer is disposed on the third portion of the upper surface of the barrier layer between the barrier layer and the drain electrode.

20. The semiconductor device according to claim 19, wherein:
the barrier layer comprises a δ-doped layer; and
the recess extends from the upper surface of the barrier layer to a portion of the barrier layer underlying the δ-doped layer.

21. The semiconductor device according to claim 19, wherein:
the barrier layer comprises a first barrier layer disposed on the channel layer and a second barrier layer disposed on the first barrier layer; and
a bandgap of the first barrier layer is larger than a bandgap of the second barrier layer.

22. The semiconductor device according to claim 19, further comprising a high dielectric material disposed at a boundary between the barrier layer and the gate electrode in the recess.

23. The semiconductor device according to claim 17, wherein:
the channel layer comprises a first semiconductor;
the barrier layer comprises a second semiconductor having a larger bandgap than the first semiconductor;
a first capping layer is disposed on the second portion of the upper surface of the barrier layer between the barrier layer and the source electrode; and
a second capping layer is disposed on the third portion of the upper surface of the barrier layer between the barrier layer and the drain electrode.

24. The semiconductor device according to claim 17, wherein a thickness of the barrier layer underlying an end portion of the gate electrode on a source electrode side is less than the thickness of the barrier layer underlying an opposite end portion of the gate electrode on a drain electrode side.

25. The semiconductor device according to claim 24, wherein the thickness of the barrier layer becomes gradually thicker from the end portion of the gate electrode on the source electrode side to the opposite end portion of the gate electrode on the drain electrode side.
